(19) United States
(12) Patent Application Publication
(10) Pub. No.: US 2013/0192760 A1
(43) Pub. Date: Aug. 1, 2013

(54) MICROWAVE EMITTING DEVICE AND SURFACE WAVE PLASMA PROCESSING APPARATUS

(71) Applicant: TOKYO ELECTRON LIMITED, Tokyo (JP)

(72) Inventors: Taro IKEDA, Yamanashi (JP); Yuki Osada, Yamanashi (JP)

(73) Assignee: TOKYO ELECTRON LIMITED, Tokyo (JP)

(21) Appl. No.: 13/755,408

(22) Filed: Jan. 31, 2013

(30) Foreign Application Priority Data
Jan. 31, 2012 (JP) 2012-018193

(51) Int. Cl. H05H 1/46; H01L 21/3065

(52) U.S. Cl. CPC H05H 1/46; H01L 21/3065
USPC 156/345.41; 315/34

(57) ABSTRACT

A microwave emitting device emits a microwave generated by a microwave generation unit into a chamber in a plasma processing apparatus for performing plasma processing by generating a surface wave plasma in the chamber. The device includes: a transmission line having a tubular outer conductor and an inner conductor disposed in the outer conductor to transmit the microwave; an antenna to emit the microwave transmitted through the microwave transmission line into the chamber through slots; a dielectric member to transmit the microwave emitted from the antenna to generate a surface wave; and a DC voltage application member to apply a positive DC voltage to a plasma generation region where a surface wave plasma is generated by the surface wave.

### CROSS-REFERENCE TO RELATED APPLICATION

This application claims priority to Japanese Patent Application No. 2012-018193 filed on Jan. 31, 2012, the entire contents of which are incorporated herein by reference.

### FIELD OF THE INVENTION

The present invention relates to a microwave emitting device and a surface wave plasma processing apparatus.

### BACKGROUND OF THE INVENTION

Plasma processing is required for manufacturing a semiconductor device. Along with the recent demand for high integration and high speed of an LSI (Large Scale Integration), a design rule of the semiconductor device configuring the LSI becomes miniaturized and a semiconductor wafer becomes scaled up. Accordingly, the plasma processing apparatus is also required to respond to such miniaturization and scaling-up.

However, in a parallel plate type plasma processing apparatus or an inductively coupled plasma processing apparatus which has been conventionally used, an electron temperature of a plasma is high, so that plasma damage may be inflicted on a microstructure. Further, since a high-density plasma region is limited, it is difficult to uniformly perform plasma processing on a scaled-up semiconductor wafer at a high speed.

Therefore, a microwave plasma processing apparatus using a radial line slot antenna has attracted attention since it is capable of uniformly generating a surface wave plasma with a high density and a low electron temperature (see, e.g., Japanese Patent Application Publication No. 2000-294550)

In a RLSA™ microwave plasma processing apparatus, a radial line slot antenna having a plurality of slots formed in a predetermined pattern is provided, as a surface wave plasma generating antenna, at an upper portion of a chamber, and a microwave guided from a microwave generation source is emitted through the slots of the antenna. Next, the microwave is emitted into the chamber maintained in a vacuum state through a dielectric microwave transmission plate provided under the antenna. Then, a surface wave plasma is generated in the chamber by the microwave electric field to process a target object such as a semiconductor wafer or the like.

In addition, there is suggested a plasma processing apparatus including a plurality of microwave emitting mechanisms having the above-described antenna for generating a surface wave plasma, wherein a microwave is divided into a plurality of microwaves and the microwaves emitted from the microwave emitting mechanisms are guided into the chamber and spatially combined in the chamber, thereby generating a plasma (see, e.g., International Publication No. 2008/013112).

In the plasma processing apparatus for generating a surface wave plasma by emitting microwaves, a generation range of the surface wave plasma is specified by an input power of the microwave or a pressure in the chamber. However, under the condition of a low power or a high pressure, the diameter of the surface wave plasma is reduced and, thus, the uniformity of the plasma density is decreased.

### SUMMARY OF THE INVENTION

In view of the above, the present invention provides a microwave emitting device and a surface wave plasma processing apparatus which can ensure a desired diameter of a surface wave plasma even when an input power of a microwave is low or a pressure is high.

In accordance with a first aspect of the present invention, there is provided with a microwave emitting device for emitting a microwave generated by a microwave generation unit into a chamber in a plasma processing apparatus for performing plasma processing by generating a surface wave plasma in the chamber. The device includes: a transmission line having a tubular outer conductor and an inner conductor coaxially disposed in the outer conductor to transmit the microwave; an antenna configured to emit the microwave transmitted through the microwave transmission line into the chamber through slots; a dielectric member configured to transmit the microwave emitted from the antenna to thereby generate a surface wave on a surface thereof; and a DC voltage application member configured to apply a positive DC voltage to a plasma generation region where a surface wave plasma is generated by the surface wave.

The DC voltage application member applies the positive DC voltage to the plasma generation region so that the surface wave plasma is expanded.

In accordance with a second aspect of the present invention, there is provided a surface wave plasma processing apparatus including: a chamber configured to accommodate a target substrate; a gas supplying unit configured to supply a gas into the chamber; a microwave generation unit configured to generate a microwave; and a plurality of microwave emitting devices configured to emit the microwave generated by the microwave generation unit into the chamber.

Each of the microwave emitting devices includes: a transmission line having a tubular outer conductor and an inner conductor coaxially disposed in the outer conductor to transmit the microwave; an antenna configured to emit the microwave transmitted through the microwave transmission line into the chamber through slots; and a dielectric member configured to transmit the microwave emitted from the antenna to thereby generate a surface wave on a surface thereof.

Plasma processing is performed on the target substrate by a surface wave plasma generated in the chamber by the microwave emitted from each of the microwave emitting devices, at least one of the microwave emitting devices includes a DC voltage application member for applying a positive DC voltage to a plasma generation region where the surface wave plasma is generated by the surface wave, and the DC voltage application member applies the positive DC voltage to the plasma generation region so that the surface wave plasma is expanded.

In accordance with the aspects of the present invention, as the DC voltage application member, a DC voltage application probe inserted into the plasma generation region may be used. The area of the surface wave plasma is preferably controlled by controlling a DC voltage applied to the DC voltage application member.

In accordance with the first aspect of the present invention, the microwave emitting device further includes a tuner configured to match a load impedance in the chamber to a characteristic impedance of the microwave generation unit. The tuner has slugs that are provided between the outer conductor and the inner conductor of the microwave transmission line and are made of a dielectric material movable along a longitudinal direction of the inner conductor, and a driving unit for moving the slugs.

### BRIEF DESCRIPTION OF THE DRAWINGS

The objects and features of the present invention will become apparent from the following description of embodiments, given in conjunction with the accompanying drawings, in which:

FIG. 1 is a cross sectional view showing a schematic configuration of a surface wave plasma processing apparatus including a microwave emitting mechanism in accordance with an embodiment of the present invention;

FIG. 2 shows a configuration of a microwave plasma source used in the surface wave plasma processing apparatus of FIG. 1;

FIG. 3 is a top view schematically showing a microwave supply unit in the microwave plasma source;

FIG. 4 is a vertical cross sectional view showing the microwave emitting mechanism used in the surface wave plasma processing apparatus of FIG. 1;

FIG. 5 is a horizontal cross sectional view showing a power supply mechanism of the microwave emitting mechanism which is taken along line V-V′ of FIG. 4;

FIG. 6 is a horizontal cross sectional view showing slugs and a sliding member of a tuner which is taken along line VI-VI′ line of FIG. 4;

FIG. 7 explains a mechanism in which a surface wave plasma is expanded by application of a voltage from a DC probe serving as a DC voltage application member;

FIG. 8 explains a mechanism in which a surface wave plasma is expanded by application of a voltage from the DC probe;

FIG. 9 shows DC currents and an actual plasma states in the case of varying a voltage applied by the DC probe;

FIG. 10 shows a relationship between an applied voltage and a diameter of a plasma; and

FIG. 11 compares diameters of a plasma generated in the case of applying a power at a DC voltage to a surface wave plasma under a reference condition and a plasma generated in the case of increasing a power of a microwave to a level that is substantially the same as that of the power of the DC voltage.

### DETAILED DESCRIPTION OF THE EMBODIMENTS

Hereinafter, an embodiment of the present invention will be described with reference to the accompanying drawings.

<Configuration of a Surface Wave Plasma Processing Apparatus>

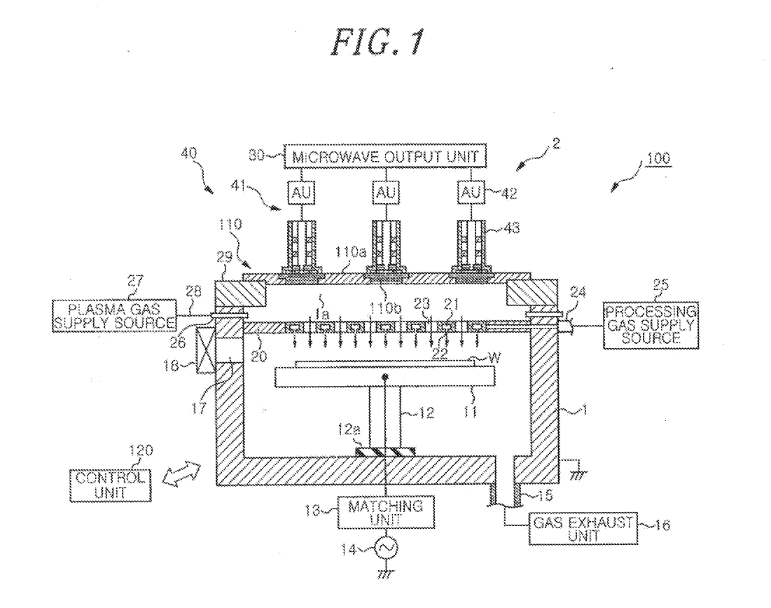

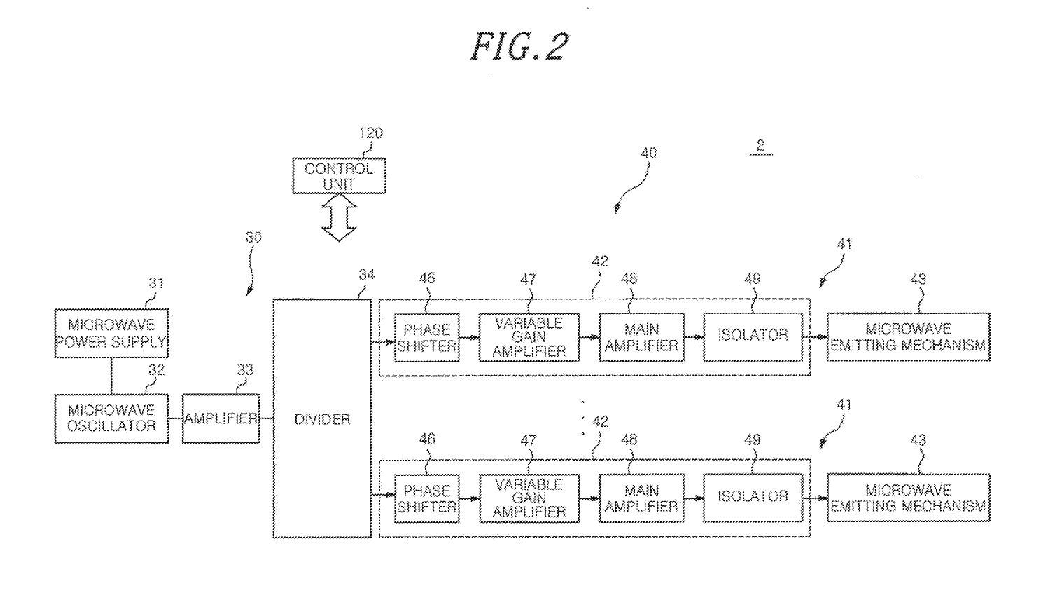

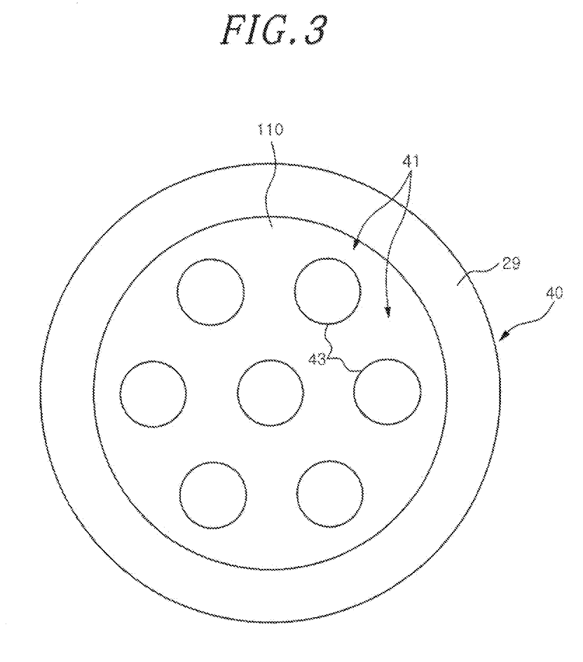

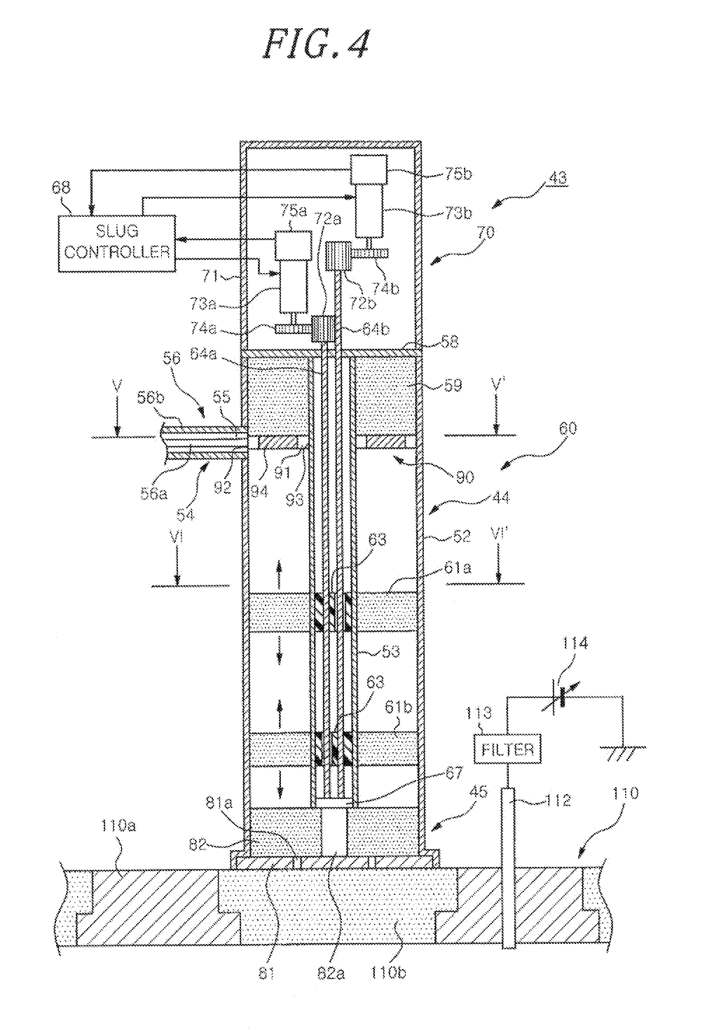

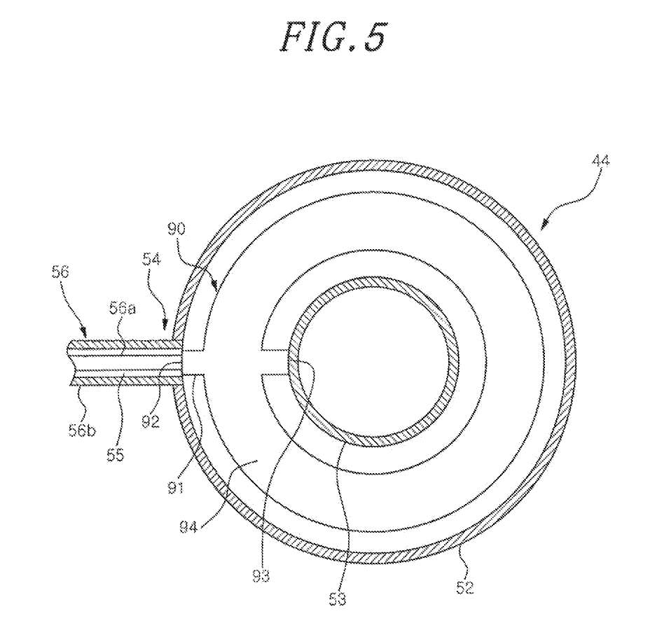

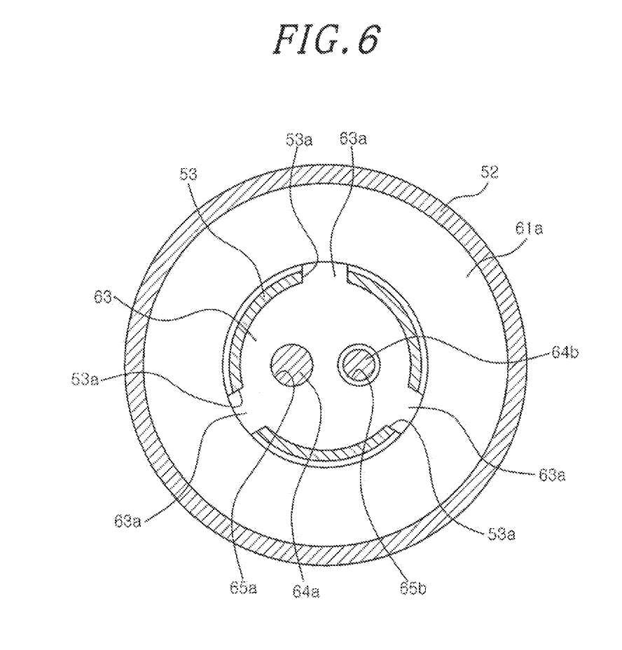

FIG. 1 is a cross sectional view showing a schematic configuration of a surface wave plasma processing apparatus including a microwave emitting mechanism in accordance with an embodiment of the present invention. FIG. 2 shows a configuration of a microwave plasma source used in the surface wave plasma processing apparatus of FIG. 1. FIG. 3 is a top view schematically showing a microwave supply unit in the microwave plasma source. FIG. 4 is a vertical cross sectional view showing the microwave emitting mechanism used in the surface wave plasma processing apparatus of FIG. 1. FIG. 5 is a horizontal cross sectional view showing a power supply mechanism of the microwave emitting mechanism which is taken along line V-V′ of FIG. 4. FIG. 6 is a horizontal cross sectional view showing a slug and a sliding member of a tuner which is taken along line VI-VI′ line of FIG. 4.

A surface wave plasma processing apparatus 100 is configured as a plasma etching apparatus for performing a plasma processing, e.g., an etching process, on a wafer. The surface wave plasma processing apparatus 100 includes an approximately cylindrical airtight chamber 1 that is grounded and made of metal such as aluminum, stainless steel or the like, and a microwave plasma source 2 for generating a microwave plasma in the chamber 1. An opening 1a is formed at a top portion of the chamber 1, and the microwave plasma source 2 is provided so as to face the inside of the chamber 1 through the opening 1a.

In the chamber 1, a susceptor 11 for horizontally supporting a semiconductor wafer W as a target object (hereinafter, referred to as “wafer”) is supported by a tubular supporting member 12 installed upwardly at a center of a bottom portion of the chamber 1 via an insulating member 12a. The susceptor 11 and the supporting member 12 are made of, e.g., aluminum having an alumite-treated (anodically oxidized) surface or the like.

Although it is not illustrated, the susceptor 11 is provided with an electrostatic chuck for electrostatically attracting the wafer W, a temperature control mechanism, a gas channel for supplying a heat transfer gas to a rear surface of the wafer W, an elevating pin that is moved up and down to transfer the wafer W and the like. Further, a high frequency bias power supply 14 is electrically connected to the susceptor 11 via a matching unit 13. By supplying a high frequency power from the high frequency bias power supply 14 to the susceptor 11, ions in the plasma are attracted to the wafer W.

A gas exhaust line 15 is connected to the bottom portion of the chamber 1, and a gas exhaust unit 16 having a vacuum pump is connected to the gas exhaust line 15. By operating the gas exhaust unit 16, the inside of the chamber 1 is exhausted and depressurized to a predetermined vacuum level at a high speed. Provided at a sidewall of the chamber 1 are a loading/unloading port 17 for loading and unloading the wafer W, and a gate valve 18 for opening and closing the loading/unloading port 17.

A shower plate 20 through which a processing gas for plasma etching is injected toward the wafer W is horizontally provided above the susceptor 11 in the chamber 1. The shower plate 20 includes grid-shaped gas channels 21 and a plurality of gas injection holes 22 formed in the gas channels 21. Spaces 23 are formed between the grid-shaped gas channels 21. A line 24 extending to the outside of the chamber 1 is connected to the gas channels 21 of the shower plate 20, and a processing gas supply source 25 is connected to the line 24.

Meanwhile, a ring-shaped plasma gas introducing member 26 is provided along a chamber wall above the shower plate 20 in the chamber 1, and a plurality of gas injection holes is formed on an inner circumference of the plasma gas introducing member 26. A plasma gas supply source 27 for supplying a plasma gas is connected to the plasma gas introducing member 26 via a line 28. As for a plasma generating gas, Ar gas or the like is preferably used. As for the processing gas, it is possible to use an etching gas, e.g., Cl₂ gas or the like.

The plasma gas introduced into the chamber 1 through the plasma gas introducing member 26 is turned into a plasma by microwave supplied from the microwave plasma source 2 into the chamber 1. The plasma thus generated passes through the spaces 23 of the shower plate 20 and excites the processing gas injected through the gas injection holes 22 of the shower plate 20. Accordingly, a plasma of the processing gas is generated. Further, the plasma gas and the processing gas may be supplied by the same supply member.

The microwave plasma source 2 has a top plate 110 supported by a supporting ring 29 provided at an upper portion of the chamber 1, and the gap between the supporting ring 29 and the top plate 110 is airtightly sealed. As shown in FIG. 2, the microwave plasma source 2 includes a microwave output unit 30 for dividedly outputting microwaves through a plurality of channels, and a microwave supply unit for transmitting the microwave outputted from the microwave output unit 30 to emit it into the chamber 1.

The microwave output unit 30 includes a microwave power supply 31, a microwave oscillator 32, an amplifier 33 for amplifying an oscillated microwave, and a divider 34 for dividing the amplified microwave into the plurality of paths.

The microwave oscillator 32 performs, e.g., a PLL (Phase Locked Loop) oscillation to generate a microwave of a predetermined frequency (e.g., 915 MHz). The divider 34 divides the microwave amplified by the amplifier 33 while matching the impedance between an input side and an output side to minimize the loss of the microwave. The frequency of the microwave ranging from 700 MHz to 3 GHz may be used in addition to 915 MHz.

The microwave supply unit 40 includes a plurality of antenna modules 41 for guiding the microwaves divided by the divider 34 into the chamber 1. Each of the antenna modules 41 includes an amplifier unit (AU) 42 for amplifying the distributed microwave and a microwave emitting mechanism 43. Further, the microwave emitting mechanism 43 has a tuner 60 for adjusting an impedance and an antenna unit 45 for emitting the amplified microwave into the chamber 1. Moreover, the microwave radiates from the antenna unit 45 of the microwave emitting mechanism 43 in each of the antenna modules 41 into the chamber 1. The microwave supply unit 40 has seven antenna modules 41, and the microwave emitting mechanisms 43 of the antenna modules 41 are arranged on the circular top plate 110 in which six microwave emitting mechanisms 43 forming a circumferential shape surround one microwave emitting mechanism 43 disposed at a central portion, as shown in FIG. 3.

The top plate 110 serves as a plate for performing vacuum sealing and transmitting microwaves and includes a metallic frame 110a and a dielectric member 110b made of a dielectric material such as quartz or the like which is fitted to the frame 110a so as to correspond to the portion where the microwave emitting mechanism 43 is provided.

The amplifier unit 42 has a phase shifter 46, a variable gain amplifier 47, a main amplifier 48 forming a solid state amplifier, and an isolator 49.

The phase shifter 46 is configured to shift the phase of the microwave, and the radiation characteristics can be modulated by controlling the phase shifter 46. For example, the directional can be controlled by adjusting the phase in each of the antenna modules to thereby change the plasma distribution. Besides, the circular polarized waves can be obtained by shifting the phase by about 90° between adjacent antenna modules. The phase shifter 46 can be used to control delay characteristics between components in amplifiers and perform spatial combination in a tuner. However, the phase shifter 46 may not be provided when it is unnecessary to modulate the radiation characteristics or control the delay characteristics between the components in the amplifiers.

The variable gain amplifier 47 controls a power level of the microwave inputted to the main amplifier 48, and thus, the variation in each of the antenna modules or the plasma intensity is adjusted. By controlling the variable gain amplifier 47 for each of the antenna modules, it is possible to variably adjust the distribution of the generated plasma.

The main amplifier 48 forming a solid state amplifier may have, e.g., an input matching circuit, a semiconductor amplifying device, an output matching circuit and a high Q resonant circuit.

The isolator 49 separates a microwave reflected by the antenna unit 45 toward the main amplifier 48. The isolator 49 has a circulator and dummy load (coaxial terminator). The circulator guides the microwave reflected by the antenna unit 45 to the dummy load, and the dummy load converts the reflected microwave guided by the circulator into a heat.

Hereinafter, the microwave emitting mechanism 43 will be described.

As shown in FIGS. 4 and 5, the microwave emitting mechanism 43 includes a coaxial waveguide (microwave transmission line) 44 of for transmitting microwave, and an antenna unit 45 for emitting the microwaves transmitted through the waveguide 44 into the chamber 1. Further, the microwaves emitted from the microwave emitting mechanisms 43 into the chamber 1 are combined in the space of the chamber 1 so that a surface wave plasma is generated in the chamber 1.

The waveguide 44 includes a tubular outer conductor 52 and a rod-shaped inner conductor 53 coaxially disposed in the outer conductor 52, and the antenna unit 45 is provided at an end portion of the waveguide 44. In the waveguide 44, the inner conductor 53 is used for power supply, and the outer conductor 52 is used for a ground. A reflecting plate 58 is provided at the upper ends of the outer conductor 52 and the inner conductor 53.

A power supply mechanism 54 for supplying a microwave (electromagnetic wave) is provided at a base end side of the waveguide 44. The power supply mechanism 54 includes a microwave power introduction port 55 provided at a side surface of the waveguide 44 (outer conductor 52) to introduce a microwave power. Connected to the microwave power introduction port 55 is a coaxial line 56 including an inner conductor 56a and an outer conductor 56b which serves as a power supply line for supplying the microwave amplified by the amplifier unit 42. A power supply antenna 90 extending horizontally toward the inside of the outer conductor 52 is connected to a leading end of the inner conductor 56a of the coaxial line 56.

The power supply antenna 90 is formed by cutting a metal plate made of, e.g., aluminum, and fitting the metal plate into a frame of a dielectric member made of Teflon (Registered Trademark) or the like. A wave retardation member 59 made of a dielectric material such as Teflon (Registered Trademark) is provided between the reflecting plate 58 and the power supply antenna 90 in order to shorten an effective wavelength of a reflection wave. In the case of using a microwave with a high frequency of, e.g., 2.45 GHz, the wave retardation member 59 may not be provided. Herein, a maximum amount of electromagnetic wave is transmitted into the coaxial waveguide 44 by optimizing a distance from the power supply antenna 90 to the reflecting plate 58 and reflecting the electromagnetic wave emitted from the power supply antenna 90 by the reflecting plate 58.

As shown in FIG. 5, the power supply antenna 90 includes an antenna main body 91 having a first pole 92 connected to the inner conductor 56a of the coaxial line 56 in the microwave power introduction port 55 and to which an electromagnetic wave is supplied and a second pole 93 for emitting the supplied electromagnetic wave; and an annular reflection portion 94 extending from both sides of the antenna main body 91 along the outer side of the inner conductor 53. The electromagnetic wave that is incident on the antenna main body 91 and the electromagnetic wave reflected by the reflection portion 94 are used to form a standing wave. The second pole 93 of the antenna main body 91 is brought into contact with the inner conductor 53.

By radiating a microwave (electromagnetic wave) from the power supply antenna 90, a microwave power is supplied to a space between the outer conductor 52 and the inner conductor 53. The microwave power supplied to the power supply mechanism 54 propagates toward the antenna unit 45.

A tuner 60 is provided in the waveguide 44. The tuner 60 serves to match an impedance of a load (plasma) in the chamber 1 to a characteristic impedance of the microwave power supply in the microwave output unit 30. The tuner 60 includes two slugs 61a and 61b that are vertically movable between the outer conductor 52 and the inner conductor 53; and a slug driving unit 70 provided at an outer side (upper side) of the reflecting plate 58.

The slug 61a is provided at the slug driving unit 70 side, and the slug 61b is provided at the antenna unit 45 side. Further, two slug moving shafts 64a and 64b used for moving the slugs 61a and 61b which are formed of screw rods each having, e.g., a trapezoidal thread, are provided in the inner space of the inner conductor 53 along the longitudinal direction.

As shown in FIG. 6, the slug 61a made of a dielectric material has an annular shape, and a sliding member 63 made of a resin having slidable property is inserted into the slug 61a. The sliding member 63 has a screw hole 65a to which the slug moving shaft 64a is screw-coupled; and a through hole 65b through which the slug moving shaft 64b is inserted.

Although the slug 61b has a screw hole 65a and a through hole 65b as in the case of the slug 61a, the screw hole 65a is screw-coupled to the slug moving shaft 64b and the slug moving shaft 64a is inserted through the through hole 65b unlike the case of the slug 61a. Accordingly, the slug 61a is vertically moved by rotating the slug moving shaft 64a, and the slug 61b is vertically moved by rotating the slug moving shaft 64b. In other words, the slugs 61a and 61b are vertically moved by a screw mechanism including the slug moving shafts 64a and 64b and the sliding member 63.

Three slits 53a are formed in the inner conductor 53 along the longitudinal direction thereof to be spaced apart from each other at a regular interval. Meanwhile, three protrusions 63a are provided at the sliding member 63 to be spaced apart from each other at a regular interval to correspond to the slits 53a. The sliding member 63 is fitted into the slugs 61a and 61b in a state where the protrusions 63a are brought into contact with the inner circumferential portions of the slugs 61a and 61b. The outer circumferential surface of the sliding member 63 comes into contact with the inner circumferential surface of the inner conductor 53 without a clearance therebetween. Thus, slug the sliding member 63 is vertically moved while sliding along the inner conductor 53 by rotating the slug moving shafts 64a and 64b. In other words, the inner circumferential surface of the inner conductor 53 functions as a slide guide of the slugs 61a and 61b.

As for a resin material of the sliding member 63, it is preferable to employ a relatively easily processible resin having high slidable property, e.g., a polyphenylene sulfide (PPS) resin.

The slug moving shafts 64a and 64b extend through the reflecting plate 58 to the slug driving unit 70. A bearing (not shown) is provided between the slug moving shafts 64a and 64b and the reflecting plate 58. Further, a bottom plate 67 made of a conductor is provided at a lower end of the inner conductor 53. The lower ends of the slug moving shafts 64a and 64b are generally formed as free ends to absorb vibration during operation, and the bottom plate 67 is separated from the lower ends of the slug moving shafts 64a and 64b by about 2 mm to 5 mm. The lower ends of the slug moving shafts 64a and 64b may be supported by the bottom plate 67 serving as a bearing unit.

The slug driving unit 70 includes a housing 71, and the slug moving shafts 64a and 64b extend into the housing 71. Gears 72a and 72b are attached to the upper ends of the slug moving shafts 64a and 64b. The slug driving unit 70 includes a motor 73a for rotating the slug moving shaft 64a; and a motor 73b for rotating the slug moving shaft 64b. The gear 74a is attached to a shaft of the motor 73a, and the gear 74b is attached to a shaft of the motor 73b. The gear 74a is engaged with the gear 72a, and the gear 74b is engaged with the gear 72b. Accordingly, the slug moving shaft 64a is rotated by the motor 73a via the gears 74a and 72a, and the slug moving shaft 64b is rotated by the motor 73b via the gears 74b and 72b. The motors 73a and 73b are, e.g., stepping motors.

The slug moving shaft 64b is longer than the slug moving shaft 64a and extends further upward than the slug moving shaft 64a. Therefore, the gears 72a and 72b are vertically offset from each other, and the motors 73a and 73b are also vertically offset from each other. Hence, the space of the power transmission mechanism including the motors, the gears and the like can be reduced, and the housing 71 has the same diameter as that of the outer conductor 52.

Incremental encoders 75a and 75b for detecting positions of the slugs 61a and 61b are provided on the motors 73a and 73b to be directly coupled to output shafts thereof, respectively.

The positions of the slugs 61a and 61b are controlled by a slug controller 68. Specifically, the slug controller 68 sends control signals to the motors 73a and 73b based on an impedance of the input terminal detected by an impedance detector (not shown) and position information of the slugs 61a and 61b detected by the encoders 75a and 75b. Then, the impedance is adjusted by controlling the positions of the slugs 61a and 61b. The slug controller 68 performs impedance matching such that an impedance of a terminal is adjusted to, e.g., about 50Ω. When only one of two slugs is moved, a trajectory passing through the origin of the smith chart is drawn. When both of the two slugs are moved, only the phase is rotated.

The antenna unit 45 serves as a microwave radiation antenna. The antenna unit 45 includes a planar slot antenna 81 having slots 81a, a wave retardation member 82 provided on the top surface of the planar slot antenna 81, and a dielectric member 110b of the top plate 110 which is provided at an end side of the planar slot antenna 81. The shape of the slots 81a is set such that the microwaves are effectively emitted. A cylindrical member 82a made of a conductor is extended through the center of the wave retardation member 82 to connect the bottom plate 67 and the planar slot antenna 81. Accordingly, the inner conductor 53 is connected to the planar slot antenna 81 via the bottom plate 67 and the cylindrical member 82a. Therefore, the lower end of the outer conductor 52 is extended to the planar slot antenna 81, and the vicinity of the wave retardation member 82 is covered by the outer conductor 52.

The wave retardation member 82 and the dielectric member 110b have a dielectric constant greater than that of vacuum and are made of quartz, ceramic, a fluorine-based resin such as polytetrafluoroethylene or the like, or a polyimide-based resin. The wave retardation member 82 and the dielectric member 110b serve to reduce a size of the antenna by shortening the wavelength of the microwave because the wavelength of the microwave is increased in the vacuum. The wave retardation member 82 can adjust the phases of the microwaves depending on its thickness. The thickness of the wave retardation member 82 is adjusted so that an antinode of the standing wave is formed at a contact portion between the top plate 110 and the planar slot antenna 81. Therefore, it is possible to maximize the radiation energy of the planar slot antenna 81 while minimizing the reflection.

The dielectric member 110b of the top plate 110 is provided to be in contact with the planar slot antenna 81. The microwave amplified by the main amplifier 48 passes through the gap between peripheral walls of the inner conductor 53 and the outer conductor 52, and then is emitted into the space in the chamber 1 through the slots 81a of the planar slot antenna 81 and the dielectric member 110b of the top plate 110.

Moreover, the microwave emitting mechanism 43 further includes a DC probe 112 as a DC voltage application member which is provided to reach the plasma generation region in the chamber 1 where a surface wave plasma is generated through the frame 110a of the top plate 110. The DC probe 112 is connected to a DC power supply 114 via a filter 113. By applying a DC voltage from the DC power supply 114 to the plasma generation region through the DC probe 112, a plasma generated in the chamber 1 by the microwave emitted from the microwave emitting mechanism 43 can be expanded, as will be described below. The DC power supply 114 has a positive pole connected to a plasma side and outputs a variable voltage.

In the present embodiment, the main amplifier 48, the tuner 60, and the planar slot antenna 81 are arranged close to one another. Further, the tuner 60 and the planar slot antenna 81 form a lumped constant circuit within 1/2 wavelength. Moreover, the planar slot antenna 81 and the wave retardation member 82 are set to have a combined resistance of about 50Ω. Therefore, the tuner 60 can directly tune the plasma load and effectively transmit an energy to the plasma.

The components in the surface wave plasma processing apparatus 100 are controlled by a control unit 120 including a micro processor. The control unit 120 includes a display, an input device, and a storage unit for storing process sequences of the surface wave plasma processing apparatus 100 and process recipes as control parameters, and the like. The control unit 120 controls the plasma processing apparatus in accordance with a selected process recipe.

### (Operation of Surface Wave Plasma Processing Apparatus)

Hereinafter, an operation of the surface wave plasma processing apparatus 100 configured as described above will be explained.

First, a wafer W is loaded into the chamber 1 and mounted on the susceptor 11. While a plasma gas, e.g., Ar gas, is introduced from the plasma gas supply source 27 into the chamber 1 through the line 28 and the plasma gas introducing member 26, a microwave is introduced from the microwave plasma source 2 into the chamber 1, thereby generating a surface wave plasma.

After the surface wave plasma is generated, a processing gas, e.g., an etching gas such as Cl₂ gas or the like, is injected from the processing gas supply source 25 into the chamber 1 through the line 24 and the shower plate 20. The injected processing gas is excited and turned into a plasma by a plasma passing through the spaces 23 of the shower plate 20. A plasma process, e.g., an etching process, is performed on the wafer W by the plasma of the processing gas.

In order to generate the surface wave plasma, in the microwave plasma source 2, a microwave power oscillated by the microwave oscillator 32 of the microwave output unit 30 is amplified by the amplifier 33 and divided into a plurality of microwave powers by the divider 34. The divided microwave powers are transmitted to the microwave supply unit 40. In the microwave supply unit 40, the microwave powers are respectively amplified by the main amplifier 48 forming a solid state amplifier and are then supplied to the waveguides 44 of the microwave emitting mechanisms 43. The impedance is automatically matched by the tuner 60. In a state where the power reflection substantially does not occur, the microwave power is emitted into the chamber 1 through the planar slot antenna 81 and the dielectric member 110b of the antenna unit 45 and is then spatially combined therein.

Since the slug driving unit 70 is provided at an extension of the shaft of the waveguide 44 having a coaxial structure, the power supply to the waveguide 44 of the microwave emitting mechanism 43 is started from the side surface thereof. In other words, when the microwave (electromagnetic wave) transmitted through the coaxial line 56 reaches the first pole 92 of the power supply antenna 90 at the microwave power introduction port 55 provided at the side surface of the waveguide 44, the microwave propagates along the antenna main body 91 and is emitted from the second pole 93 disposed at the leading end of the antenna main body 91. Further, the microwave propagating in the antenna main body 91 is reflected by the reflection portion 94 and combined with an incident wave, thereby generating a standing wave. When the standing wave is generated at the location of the power supply antenna 90, a magnetic field is induced along the outer wall of the inner conductor 53 and, thus, an electromagnetic field is induced. Due to such chain reactions, the microwave propagates in the waveguide 44 and is transmitted to the antenna unit 45.

Further, in the waveguide 44, a maximum microwave (electromagnetic wave) power can be transmitted to the waveguide 44 having a coaxial structure by reflecting the microwave emitted from the power supply antenna 90 by the reflecting plate 58. In that case, the length from the power supply antenna 90 to the reflecting plate 58 is preferably set to be substantially a multiple of a half wavelength of λg/4 to effectively combine the microwave with the reflection wave.

The microwave emitting mechanism 43 is very compact because the antenna unit 45 and the tuner 60 are formed as one unit. Therefore, it is possible to make the microwave plasma source 2 compact. The main amplifier 48, the tuner 60 and the planar slot antenna 81 are provided adjacent to one another. Especially, the tuner 60 and the planar slot antenna 81 can constitute a lumped constant circuit. Moreover, a plasma load can be tuned with high precision by the tuner 60 by setting a combined resistance of the planar slot antenna 81, the wave retardation member 82, and the dielectric member 110b to about 50Ω. The tuner 60 constitutes a slug tuner capable matching an impedance simply by moving the two slugs 61a and 61b and thus is compact and has low loss. Since the tuner 60 and the planar slot antenna 81 adjacent to each other constitute a lumped constant circuit and function as a resonator, an impedance mismatch up to the planar slot antenna 81 can be solved with high precision. Further, a mismatching portion can practically be used as a plasma space, so that plasma control can be performed with high precision by the tuner 60.

The driving transmission unit for driving the slugs, the driving guide unit and the support unit are provided inside the inner conductor 53, so that the driving mechanism of the slugs 61a and 61b can be scaled down and the microwave emitting mechanism 43 can also be scaled down.

However, when a surface wave plasma is generated by emitting electromagnetic wave (microwave) from the antenna to generate a plasma as in the present embodiment, the generation range of the surface wave plasma is generally determined by an input power of a microwave or a pressure in the chamber. Therefore, the diameter of the surface wave plasma is reduced and the uniformity of the plasma density deteriorates under the conditions in which an input power is low or a pressure is high.

Therefore, in the present embodiment, a DC probe 112 as a DC voltage application member is provided with the microwave emitting mechanism 43 to extend into the plasma generation area in the chamber 1 through the frame 110a of the top plate 110, and a positive voltage is applied to the DC probe 112. Accordingly, the surface wave plasma is expanded and, thus, the uniformity of the plasma density can be enhanced.

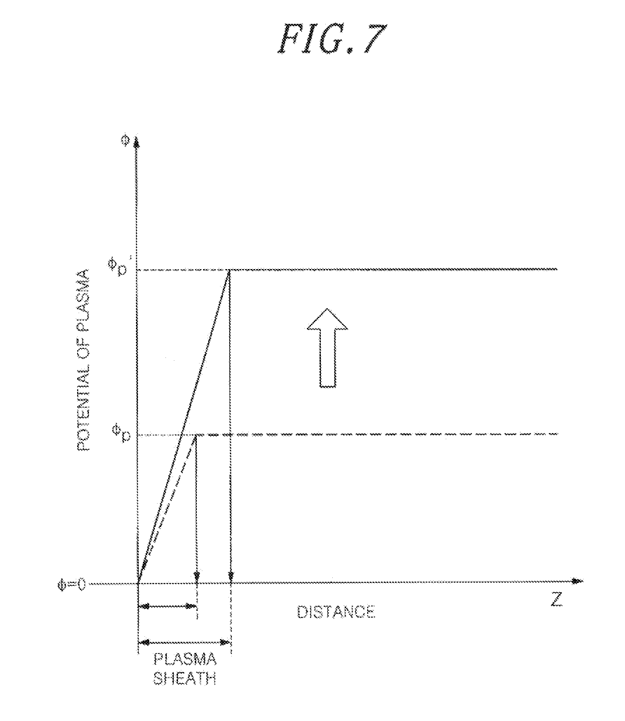

The reason that the plasma is expanded by the application of the DC voltage by the DC probe 112 is because the plasma sheath can be controlled by applying a positive DC voltage from the DC probe 112. In other words, in the case of using the DC probe 112 as a DC voltage application member, when the voltage applied to the DC probe 112 is increased, DC discharge is produced between the DC probe 112 and the plasma. This leads to destruction of the plasma sheath at that portion, so that the voltage can be directly applied to the plasma. Accordingly, the potential of the plasma is increased, and the potential difference with the plasma potential at a grounded portion is increased, which makes the plasma sheath thicker, as shown in FIG. 7.

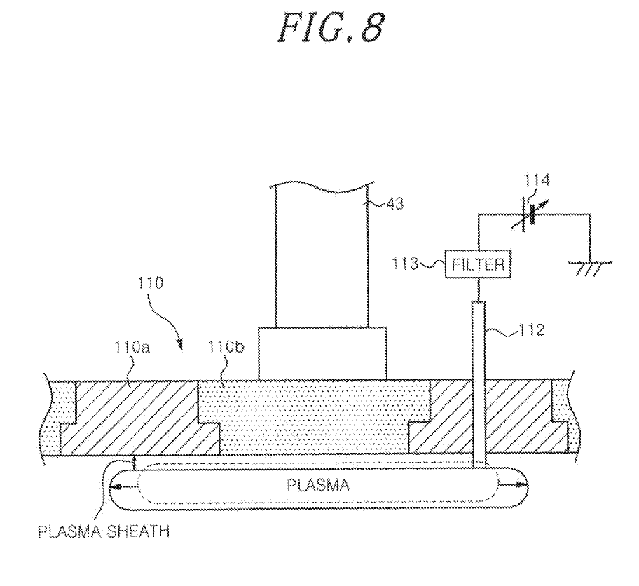

When the plasma sheath becomes thick, an attenuation constant of a TE fundamental wave propagating in the plasma sheath is decreased, and the propagation distance of the TE fundamental wave is increased. In other words, the microwave can easily propagate. Thus, the surface wave plasma generated by the TE fundamental wave as an excited surface wave is expanded, and this leads to an increase of the diameter of the surface wave plasma as shown in FIG. 8. Since the diameter of the surface wave plasma and the plasma density has a monotonic increase relationship, the power absorption of the plasma is increased by the amount corresponding to the expansion of the surface wave plasma, which results in improvement of the efficiency.

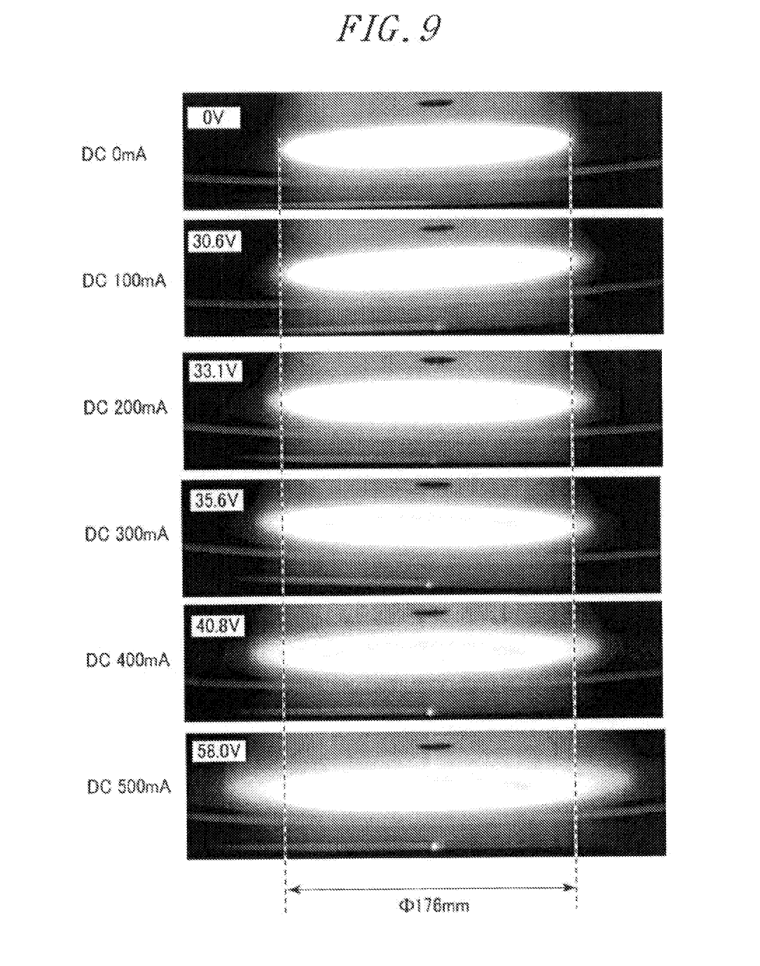

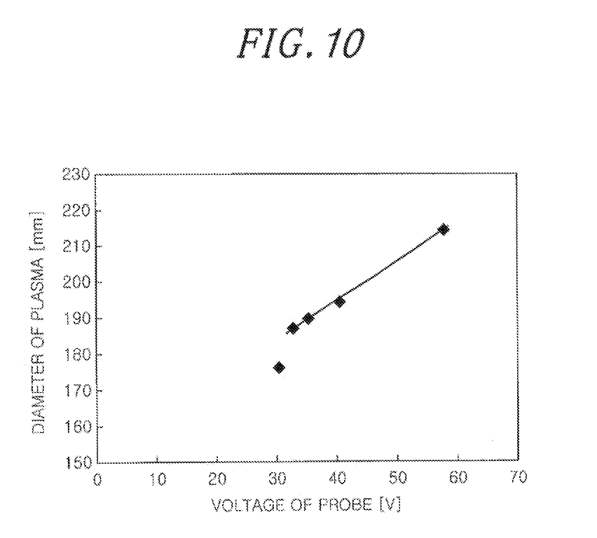

FIG. 9 shows a DC current and an actual plasma state in the case of varying a voltage applied from the DC probe 112. FIG. 10 shows relationship between an applied voltage and a diameter of a plasma. As shown in FIGS. 9 and 10, the voltage applied to the plasma from the DC probe 112 is in substantially direct proportion to the diameter of plasma.

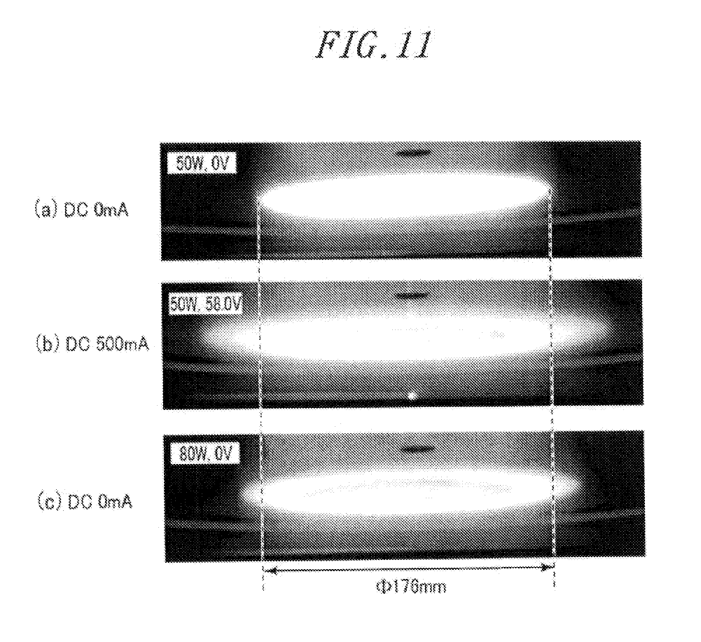

Next, a test for examining a plasma expansion effect in the case of applying a DC voltage will be described. Here, a case of generating a surface wave plasma by emitting microwaves having a power of about 50 W from the microwave emitting mechanism without applying a DC voltage (reference condition) was compared with a case of applying a DC voltage of about 58 V (DC current: 500 mA, total power: about 80 W) in addition to the reference condition and a case of applying microwaves having a power of about 80 W without applying a DC voltage to thereby monitor actual plasma states in the respective cases. FIG. 11 shows images of the plasma states. As shown in FIG. 11, although the increases of the powers in the case (b) of applying a power of a DC voltage and in the case (c) of increasing a power of microwave with respect to the reference condition of the case (a) (power of microwave 50 W) were substantially the same, the effect in which a plasma is expanded was higher in the case of applying a DC voltage.

By applying a positive DC voltage from the DC probe 112 as a DC voltage application member to the surface wave plasma generation area, the surface wave plasma generated by the microwave emitting mechanism 43 can be expanded, and this can improve the uniformity of the plasma density. Further, the area of the surface wave plasma can be controlled by controlling an applied DC voltage, and, thus, the uniformity of the plasma density can be controlled.

In that case, the DC probe 112 may be provided for each of the microwave emitting mechanisms 43. However, it is unnecessary to provide the DC probe 112 for all of microwave emitting mechanisms 43, and the DC probe 112 is preferably provided for at least one microwave emitting mechanism 43. For example, even if the DC probe 112 is provided only with the microwave emitting mechanism 43 disposed at the center and a DC voltage is applied therefrom, the surface wave plasma at the central portion can be expanded. Hence, the plasma can be expanded to portions having a low plasma density between the central surface wave plasma and the surface wave plasmas generated by peripheral microwave emitting mechanisms 43, and this leads to improvement of the uniformity of the plasma.

When two or more microwave emitting mechanisms 43 are provided with the DC probes 112, the areas of the plasmas generated by the microwave emitting mechanisms 43 can be independently controlled by individually controlling DC voltages applied from the DC probes 112. As a result, the controllability of the plasma can be considerably improved.

<Other Application>

The present invention is not limited to the above embodiments and may be variously modified within the scope of the present invention. For example, although the example in which a DC probe is used as a DC voltage application member has been described in the above embodiments, it is not limited thereto, and another shape such as a block shape, a ring shape that is coaxial with the microwave emitting mechanism or the like may also be employed. Moreover, the configurations of the microwave output unit 30, the microwave supply unit 40 and the like are not limited to those of the embodiments. For example, the phase shifter may not be provided when it is unnecessary to control the directivity of the microwave emitted from the antenna or to form a circular polarized wave.

In the above embodiments, an etching apparatus has been described as an example of a plasma processing apparatus. However, the present invention is not limited thereto and may be applied to another plasma processing apparatus for performing film formation, oxynitride film processing, ashing, or the like. Further, the substrate to be processed is not limited to the semiconductor wafer W, and may be another substrate such as a substrate for use in a flat panel display (FPD) represented by a liquid crystal display (LCD), a ceramic substrate or the like.

While the invention has been shown and described with respect to the embodiments, it will be understood by those skilled in the art that various changes and modification may be made without departing from the scope of the invention as defined in the following claims.

What is claimed is:

1. A microwave emitting device for emitting a microwave generated by a microwave generation unit into a chamber in a plasma processing apparatus for performing plasma processing by generating a surface wave plasma in the chamber, the device comprising:
a transmission line having a tubular outer conductor and an inner conductor coaxially disposed in the outer conductor to transmit the microwave;
an antenna configured to emit the microwave transmitted through the microwave transmission line into the chamber through slots;
a dielectric member configured to transmit the microwave emitted from the antenna to thereby generate a surface wave on a surface thereof; and
a DC voltage application member configured to apply a positive DC voltage to a plasma generation region where a surface wave plasma is generated by the surface wave,
wherein the DC voltage application member applies the positive DC voltage to the plasma generation region so that the surface wave plasma is expanded.

2. The microwave emitting device of claim 1, wherein the DC voltage application member is a DC voltage application probe inserted into the plasma generation region.

3. The microwave emitting device of claim 1, wherein an area of the surface wave plasma is controlled by controlling a DC voltage applied to the DC voltage application member.

4. The microwave emitting device of claim 2, wherein an area of the surface wave plasma is controlled by controlling a DC voltage applied to the DC voltage application member.

5. The microwave emitting device of claim 1, further comprising: a tuner configured to match a load impedance in the chamber to a characteristic impedance of the microwave generation unit,
wherein the tuner has slugs that are provided between the outer conductor and the inner conductor of the microwave transmission line and are made of a dielectric material movable along a longitudinal direction of the inner conductor, and a driving unit for moving the slugs.

6. The microwave emitting device of claim 2, further comprising: a tuner configured to match a load impedance in the chamber to a characteristic impedance of the microwave generation unit,
wherein the tuner has slugs that are provided between the outer conductor and the inner conductor of the microwave transmission line and are made of a dielectric material movable along a longitudinal direction of the inner conductor, and a driving unit for moving the slugs.

7. The microwave emitting device of claim 3, further comprising: a tuner configured to match a load impedance in the chamber to a characteristic impedance of the microwave generation unit,
wherein the tuner has slugs that are provided between the outer conductor and the inner conductor of the microwave transmission line and are made of a dielectric material movable along a longitudinal direction of the inner conductor, and a driving unit for moving the slugs.

8. The microwave emitting device of claim 4, further comprising: a tuner configured to match a load impedance in the chamber to a characteristic impedance of the microwave generation unit,
wherein the tuner has slugs that are provided between the outer conductor and the inner conductor of the microwave transmission line and are made of a dielectric material movable along a longitudinal direction of the inner conductor, and a driving unit for moving the slugs.

9. A surface wave plasma processing apparatus comprising:
a chamber configured to accommodate a target substrate;
a gas supplying unit configured to supply a gas into the chamber;
a microwave generation unit configured to generate a microwave; and
a plurality of microwave emitting devices configured to emit the microwave generated by the microwave generation unit into the chamber,
wherein each of the microwave emitting devices includes:
a transmission line having a tubular outer conductor and an inner conductor coaxially disposed in the outer conductor to transmit the microwave;
an antenna configured to emit the microwave transmitted through the microwave transmission line into the chamber through slots; and
a dielectric member configured to transmit the microwave emitted from the antenna to thereby generate a surface wave on a surface thereof,
wherein plasma processing is performed on the target substrate by a surface wave plasma generated in the chamber by the microwave emitted from each of the microwave emitting devices,
at least one of the microwave emitting devices includes a DC voltage application member for applying a positive DC voltage to a plasma generation region where the surface wave plasma is generated by the surface wave, and
the DC voltage application member applies the positive DC voltage to the plasma generation region so that the surface wave plasma is expanded.

10. The plasma processing apparatus of claim 9, wherein the DC voltage application member is a DC voltage application probe inserted into the plasma generation region.

11. The plasma processing apparatus of claim 9, wherein an area of the surface wave plasma is controlled by controlling a DC voltage applied to the DC voltage application member.

12. The plasma processing apparatus of claim 10, wherein an area of the surface wave plasma is controlled by controlling a DC voltage applied to the DC voltage application member.

13. The plasma processing apparatus of claim 9, wherein each of two or more of the microwave emitting devices includes the DC voltage application member, and an area of the surface wave plasma is independently controlled by independently applying a DC voltage to the DC voltage application member.

14. The plasma processing apparatus of claim 10, wherein each of two or more of the microwave emitting devices includes the DC voltage application member, and an area of the surface wave plasma is independently controlled by independently applying a DC voltage to the DC voltage application member.

15. The plasma processing apparatus of claim 11, wherein each of two or more of the microwave emitting devices includes the DC voltage application member, and an area of the surface wave plasma is independently controlled by independently applying a DC voltage to the DC voltage application member.

16. The plasma processing apparatus of claim 12, wherein each of two or more of the microwave emitting devices includes the DC voltage application member, and an area of the surface wave plasma is independently controlled by independently applying a DC voltage to the DC voltage application member.
